(19) United States
(12) Patent Application Publication
(10) Pub. No.: US 2016/0260925 A1
(43) Pub. Date: Sep. 8, 2016

(54) ORGANIC ELECTROLUMINESCENT DEVICE AND METHOD FOR PREPARING THE SAME, AND DISPLAY APPARATUS

(71) Applicant: BOE TECHNOLOGY GROUP CO., LTD., Beijing (CN)

(72) Inventor: Wenjun HOU, Beijing (CN)

(73) Assignee: BOE TECHNOLOGY GROUP CO., LTD., Beijing (CN)

(21) Appl. No.: 14/768,953

(22) PCT Filed: Nov. 6, 2014
(86) PCT No.: PCT/CN2014/090513

§ 371 Date: Aug. 19, 2015

(30) Foreign Application Priority Data
Aug. 26, 2014 (CN) 201410425559.9

(51) Int. Cl. H01L 51/52

(52) U.S. Cl. CPC H01L 51/5246; H01L 51/525; H01L 2251/301; H01L 2251/303

(57) ABSTRACT

An electroluminescent device and a method for preparing the same, and a display apparatus are disclosed. The organic electroluminescent device comprises a substrate (1) and a cover plate (2) disposed opposite to each other; an electroluminescent structure (3) disposed between the substrate (1) and the cover plate (2); and a barrier wall (4) for blocking water and oxygen, which is located around the electroluminescent structure (3) and forms a closed ring structure. The barrier wall (4) for blocking water and oxygen is located between the substrate (1) and the cover plate (2), is assembled with the substrate (1) and the cover plate (2) in a sealing manner to form a sealed space (6), and comprises a plurality of barrier layers (41) for blocking water and oxygen with an interval therebetween, the barrier layers (41) being made of an inorganic material; a sealant (5) is provided between each two adjacent barrier layer (41) for blocking water and oxygen to connect the substrate (1) and the cover plate (2). The organic electroluminescent device can effectively block water and oxygen and reduce permeability of water and oxygen so as to increase its lifetime.

### TECHNICAL FIELD

At least one embodiment of the present invention relates to an organic electroluminescent device and a method for preparing the same, and a display apparatus.

### BACKGROUND

Organic electroluminescent devices are very sensitive to oxygen and water vapor, and water and oxygen penetrated into the devices will seriously affect the luminescence lifetime of the devices. On the one hand, oxygen and the carbonyl compound generated by oxidation of a light emitting layer in an organic light emitting diode (OLED) are effective quenchers, which will seriously reduce the luminescence efficiency of OLED devices; on the other hand, water can hydrolyze organic layer compounds and affect their conductivity, resulting in reduced stability of the material, and active metal electrodes can easily be eroded by water and oxygen, and may even result in the occurrence of electrochemical corrosion, thereby affecting the lifetime of OLED devices. Therefore, good sealing is a requirement for obtaining a stable OLED device.

### SUMMARY

At least one embodiment of the present invention provides an organic electroluminescent device and a method for preparing the same, and a display apparatus, the organic electroluminescent device being capable of effectively blocking water and oxygen and reducing permeability of water and oxygen.

At least one embodiment of the present invention provides an organic electroluminescent device, comprising: a substrate; a cover plate disposed opposite to the substrate; an electroluminescent structure disposed on the substrate and located between the substrate and the cover plate; and a barrier wall configured for blocking water and oxygen, which is located around the electroluminescent structure and forms a closed ring structure. The barrier wall configured for blocking water and oxygen is located between the substrate and the cover plate and is assembled with the substrate and the cover plate in a sealing manner to form a sealed space; the barrier wall configured for blocking water and oxygen comprises a plurality of barrier layers configured for blocking water and oxygen with an interval therebetween and being made of an inorganic material; a sealant is provided between each two adjacent barrier layers configured for blocking water and oxygen to connect the substrate and the cover plate.

At least one embodiment of the present invention provides a method for preparing an organic electroluminescent device, the method comprising: forming an inorganic film on one of the substrate and the cover plate and forming the inorganic film into a pattern of a barrier wall configured for blocking water and oxygen by a patterning process such that the barrier wall configured for blocking water and oxygen forms a closed ring structure, wherein the barrier wall configured for blocking water and oxygen comprises a plurality of barrier layers configured for blocking water and oxygen with an interval therebetween; filling up a space between each two adjacent barrier layers configured for blocking water and oxygen with a sealant; and packaging the substrate and the cover plate such that the barrier wall configured for blocking water and oxygen is assembled with the substrate and the cover plate in a sealing manner to form a sealed space.

At least one embodiment of the present invention provides a display apparatus, comprising the above organic electroluminescent device.

### BRIEF DESCRIPTION OF THE DRAWINGS

In order to illustrate the technical solutions of the embodiments of the present invention more clearly, the figures of the embodiments are simply described below. Apparently, the figures described below merely relate to some embodiments of the present invention rather than are limitative of the present invention.

FIG. 1 is a schematic view of an organic electroluminescent device provided in an embodiment of the present invention.

FIG. 2 is a flow chart of a method for preparing an organic electroluminescent device provided in an embodiment of the present invention.

### DETAILED DESCRIPTION

To make the object, technical solutions, and advantages of the present invention clearer, the technical solutions of the embodiments of the present invention will be described below in a clearer and more complete way with reference to the figures of the embodiments of the present invention. Apparently, the embodiments described are only part, rather than all of the embodiments of the present invention. Based on the embodiments of the present invention described, all the other embodiments obtained by a person of ordinary skill in the art without paying inventive work fall within the scope of protection of the present invention.

The inventors of the present application have noted that a sealant is generally used in methods for packaging OLED devices. However, sealants will contain micropores during use, which easily allows water and oxygen to penetrate into devices, thereby affecting the lifetime of OLED devices. Hence, a person of ordinary skill in the art hopes to better reduce the permeability of water and oxygen in OLED device package.

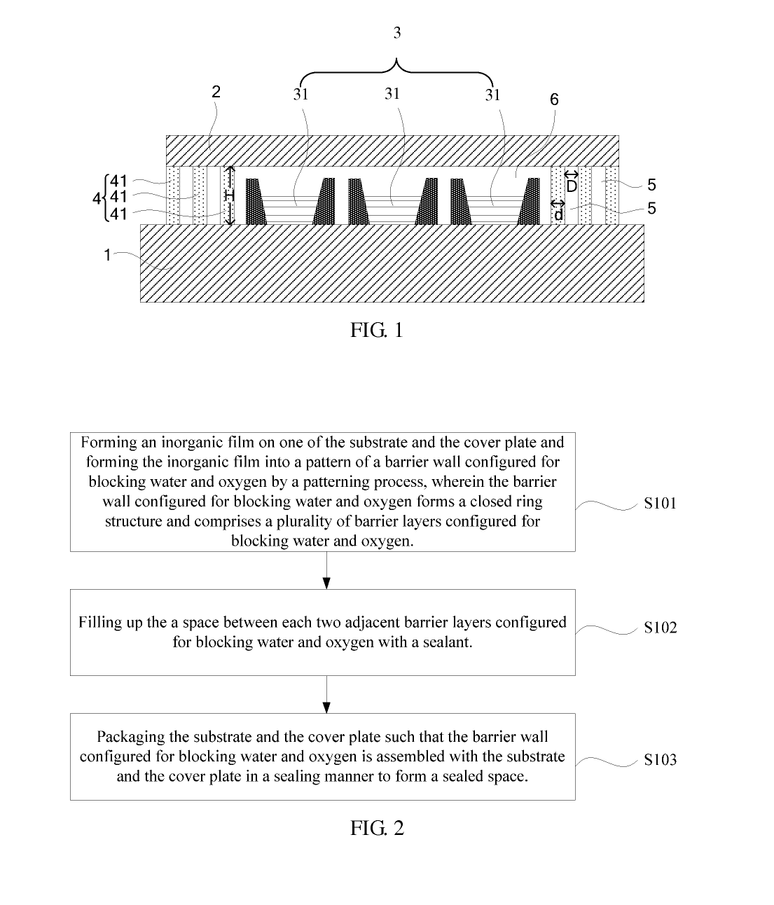

Referring to FIG. 1, FIG. 1 is a schematic view of an organic electroluminescent device provided in an embodiment of the present invention.

As shown in FIG. 1, the organic electroluminescent device provided by at least one embodiment of the present invention comprises: a substrate 1; a cover plate 2 disposed opposite to the substrate 1; an electroluminescent structure 3 disposed on the substrate 1 and located between the substrate 1 and the cover plate 2; and a barrier wall configured for blocking water and oxygen 4, which is located around the electroluminescent structure 3 and forms a closed ring structure. The barrier wall configured for blocking water and oxygen 4 is located between the substrate 1 and the cover plate 2 and is assembled with the substrate 1 and the cover plate 2 in a sealing manner to form a sealed space 6; the barrier wall configured for blocking water and oxygen 4 comprises a plurality of barrier layers configured for blocking water and oxygen 41 with an interval therebetween and being made of an inorganic material; a space between each two adjacent barrier layers configured for blocking water and oxygen 41 is provided with a sealant 5 to connect the substrate 1 and the cover plate 2.

For example, as shown in FIG. 2, the electroluminescent structure 3 may comprise a plurality of light emitting units 31, each of the light emitting units 31 including, for example, an anode, a light emitting layer, a cathode and the like.

In the organic electroluminescent device described above, the barrier wall configured for blocking water and oxygen 4 is located between the substrate 1 and the cover plate 2 and comprises a barrier layer configured for blocking water and oxygen 41 made of an inorganic material, wherein a space between each two adjacent barrier layers configured for blocking water and oxygen 41 is filled up with a sealant 5 connecting the substrate 1 and the cover plate 2 such that the substrate 1, the cover plate 2 and the barrier layers configured for blocking water and oxygen 41 are connected in a sealing manner to form a sealed space 6 located among the substrate 1, the cover plate 2 and the barrier wall configured for blocking water and oxygen 4, the electroluminescent structure 3 being located in the sealed space 6; along the direction of the outer side of the sealed space 6 pointing to the inner side of the sealed space 6, the barrier wall configured for blocking water and oxygen 4 comprises a plurality of barrier layers configured for blocking water and oxygen 41 made of an inorganic material, wherein a space between each two adjacent barrier layers configured for blocking water and oxygen 41 is filled up with a sealant 5 connecting the substrate 1 and the cover plate 2 so as to form an alternating structure of the inorganic barrier layer configured for blocking water and oxygen 41 and the sealant 5. The alternating structure of an inorganic layer and an organic layer can effectively block water and oxygen and reduce permeability of water and oxygen, thereby increasing the lifetime of the organic electroluminescent device.

In at least one embodiment, the inorganic material can be selected from the group consisting of SiO₂, SiNₓ and Al₂O₃. Needless to say, the present invention is not limited by the embodiment.

On the basis of the above embodiments, in the organic electroluminescent device provided in one embodiment, a distance H between a side surface of the substrate 1 facing the cover plate 2 and a side surface of the cover plate 2 facing the substrate 1 can be 0.01 to 10 μm. A specific numerical value for the distance H can be set according to requirements so as to control the height of the barrier wall configured for blocking water and oxygen 4 in the above electroluminescent device, which facilitates a small dimension design of the electroluminescent device along the direction perpendicular to the substrate 1.

In at least one embodiment, on the basis of the above organic electroluminescent device, along the direction of the outer side of the closed ring structure pointing to the inner side of the closed ring structure: a thickness d of each barrier layer configured for blocking water and oxygen 41 can be 0.01 to 200 μm; and/or a distance D between two opposite side surfaces of each two adjacent barrier layers configured for blocking water and oxygen 41 can be 0.01 to 200 μm.

Along the direction of the outer side of the closed ring structure pointing to the inner side of the closed ring structure, the thickness d of the barrier layer configured for blocking water and oxygen 41 and the distance D between two opposite side surfaces of each two adjacent barrier layers configured for blocking water and oxygen 41 can be set according to requirements so as to control the width of the barrier wall configured for blocking water and oxygen 4 in the above electroluminescent device, which facilitates a narrow frame design of the electroluminescent device.

Referring to FIG. 1 and FIG. 2, FIG. 2 is a flow chart of a method for preparing an electroluminescent device provided in embodiments of the present invention.

As shown in FIG. 1 and FIG. 2, the method for preparing an electroluminescent device provided in at least one embodiment of the present invention comprises the following steps S101 to S103.

Step S101. Forming an inorganic film on one of the substrate 1 and the cover plate 2 and forming the inorganic film into a pattern of a barrier wall configured for blocking water and oxygen 4 by a patterning process, wherein the barrier wall configured for blocking water and oxygen 4 forms a closed ring structure and comprises a plurality of barrier layers configured for blocking water and oxygen 41 with an interval therebetween.

Step S102. Filling up a space between each two adjacent barrier layers configured for blocking water and oxygen 41 with a sealant 5.

Step S103. Packaging the substrate 1 and the cover plate 2 such that the barrier wall configured for blocking water and oxygen 4 is assembled with the substrate 1 and the cover plate 2 in a sealing manner to form a sealed space 6.

In the organic electroluminescent device obtained by the above method for preparing an electroluminescent device, in Step S101, the barrier wall configured for blocking water and oxygen 4 is made of an inorganic film, is formed on one of the substrate 1 and the cover plate 2, and comprises a plurality of barrier layers configured for blocking water and oxygen 41; in Step S102, the space between each two adjacent barrier layers configured for blocking water and oxygen 41 is filled up with a sealant 5; in Step 103, the sealant 5 assembles the barrier wall configured for blocking water and oxygen 4 with the substrate 1 and the cover plate 2 in a sealing manner such that the substrate 1, the cover plate 2 and the barrier layer configured for blocking water and oxygen 41 are connected in a sealing manner to form a sealed space 6 located among the substrate 1, the cover plate 2 and the barrier wall configured for blocking water and oxygen 4, the electroluminescent structure 3 being located in the sealed space 6. However, in Step S101, along the direction of the outer side of the sealed space 6 pointing to the inner side of the sealed space 6, the barrier wall configured for blocking water and oxygen 4 comprises a plurality of barrier layers configured for blocking water and oxygen 41 made of an inorganic material, and the space between each two adjacent barrier layers configured for blocking water and oxygen 41 is filled up with a sealant 5 so as to form an alternating structure of the inorganic barrier layer configured for blocking water and oxygen 41 and the sealant 5. The alternating structure of an inorganic layer and an organic layer can effectively block water and oxygen and reduce permeability of water and oxygen, thereby increasing the lifetime of the organic electroluminescent device.

In one embodiment, the preparation method further comprises: preparing an organic electroluminescent structure 3 on the substrate 1 and within a region corresponding to the closed ring structure. For example, when a barrier wall configured for blocking water and oxygen 4 is formed on a substrate 1, prior to Step S102, i.e., prior to filling up the space between each two adjacent barrier layers configured for blocking water and oxygen 41 with a sealant 5, the preparation method further comprises: preparing an organic electroluminescent structure 3 on the substrate 1 and within the closed ring structure. For example, when a barrier wall configured for blocking water and oxygen 4 is formed on a cover plate 2, the order of the step of filling with a sealant 5 and the step of preparing an electroluminescent structure 3 is not limited because the electroluminescent structure 3 and the barrier wall configured for blocking water and oxygen 4 are formed on different substrates.

On the basis of the above embodiments, in at least one embodiment, in step S101, the inorganic film has a thickness of 0.01 to 10 μm. The thickness is the distance H between a side surface of the substrate 1 facing the cover plate 2 and a side surface of the cover plate 2 facing the substrate 1. The specific numerical value of the distance H can be set according to requirements so as to control the height of the barrier wall configured for blocking water and oxygen 4 in the above electroluminescent device, which facilitates a small dimension design of the electroluminescent device along the direction perpendicular to the substrate 1.

In at least one embodiment, in Step S101, the material of the inorganic film can be SiO₂, SiNₓ, or Al₂O₃.

On the basis of the above various embodiments, in an embodiment, in Step S101, the distance between two opposite side surfaces of each two adjacent barrier layers configured for blocking water and oxygen 41 can be 0.01 to 200 μm.

On the basis of the above various embodiments, in an embodiment, in Step S101, an inorganic film is formed on the substrate 1, for example: the inorganic film is formed by a process selected from the group consisting of plasma enhanced chemical vapor deposition (PECVD), atomic layer deposition (ALD), or a plasma sputtering method.

In at least one embodiment, a distance between a face of the substrate facing the cover plate and a face of the cover plate facing the substrate can be 0.01 to 10 μm.

At least one embodiment of the present invention further provides a display apparatus, comprising the organic electroluminescent device according to any of the above embodiments. The display apparatus may be: any product or component having display function such as an electronic paper, an OLED panel, a mobile phone, a tablet computer, a TV set, a display, a laptop, a digital picture frame, a navigator or the like.

The above are merely exemplary embodiments of the present invention, and are not intended to limit the scope of protection of the present invention, which is yet determined by the appended claims.

The present application claims the priority of the Chinese Patent Application No. 201410425559.9 submitted on Aug. 26, 2014, and the content disclosed in the above Chinese patent application is incorporated herein by reference as part of this application.

1. An organic electroluminescent device comprising:
a substrate;
a cover plate disposed opposite to the substrate;
an electroluminescent structure disposed on the substrate and located between the substrate and the cover plate; and
a barrier wall configured for blocking water and oxygen, which is located around the electroluminescent structure and forms a closed ring structure,
wherein:
the barrier wall configured for blocking water and oxygen is located between the substrate and the cover plate and is assembled with the substrate and the cover plate in a sealing manner to form a sealed space in which the electroluminescent structure is disposed; the barrier wall configured for blocking water and oxygen comprises a plurality of barrier layers for blocking water and oxygen with an interval therebetween, the barrier layers being made of an inorganic material; and a sealant is provided between each two adjacent barrier layers for blocking water and oxygen to connect the substrate and the cover plate.

2. The organic electroluminescent device according to claim 1, wherein the inorganic material is selected from the group consisting of SiO₂, SiNₓ, and Al₂O₃.

3. The organic electroluminescent device according to claim 1, wherein a distance between a side surface of the substrate facing the cover plate and a side surface of the cover plate facing the substrate is 0.01 to 10 μm.

4. The organic electroluminescent device according to claim 1, wherein each of the barrier layers for blocking water and oxygen has a thickness of 0.01 to 200 μm.

5. The organic electroluminescent device according to claim 1, wherein a distance between two opposite side surfaces of each two adjacent barrier layers for blocking water and oxygen is 0.01 to 200 μm.

6. A method for preparing the organic electroluminescent device according to claim 1, comprising:
forming an inorganic film on one of the substrate and the cover plate and forming the inorganic film into a pattern of the barrier wall for blocking water and oxygen by a patterning process, wherein the barrier wall for blocking water and oxygen forms the closed ring structure and comprises the plurality of barrier layers for blocking water and oxygen with an interval therebetween;
filling up a space between each two adjacent barrier layers for blocking water and oxygen with the sealant; and
packaging the substrate and the cover plate such that the barrier wall for blocking water and oxygen is assembled with the substrate and the cover plate in a sealing manner to form the sealed space.

7. The preparation method according to claim 6, further comprising:
preparing the organic electroluminescent structure on the substrate and within a region corresponding to the closed ring structure.

8. The preparation method according to claim 6, wherein the inorganic film has a thickness of 0.01 to 10 μm.

9. The preparation method according to claim 6, wherein a distance between two opposite side surfaces of each two adjacent barrier layers for blocking water and oxygen is 0.01 to 200 μm.

10. The preparation method according to claim 6, wherein the inorganic film is formed by a process selected from the group consisting of plasma enhanced chemical vapor deposition, atomic layer deposition, and a plasma sputtering method.

11. The preparation method according to claim 6, wherein the material of the inorganic film is selected from the group consisting of SiO₂, SiNₓ, and Al₂O₃.

12. The preparation method according to claim 6, wherein a distance between a side surface of the substrate facing the cover plate and a side surface of the cover plate facing the substrate is 0.01 to 10 μm.

13. A display apparatus comprising the organic electroluminescent device according to claim 1.

14. The organic electroluminescent device according to claim 2, wherein a distance between a side surface of the substrate facing the cover plate and a side surface of the cover plate facing the substrate is 0.01 to 10 μm.

15. The organic electroluminescent device according to claim 2, wherein each of the barrier layers for blocking water and oxygen has a thickness of 0.01 to 200 μm.

16. The organic electroluminescent device according to claim 2, wherein a distance between two opposite side surfaces of each two adjacent barrier layers for blocking water and oxygen is 0.01 to 200 μm.

17. The preparation method according to claim 7, wherein the inorganic film has a thickness of 0.01 to 10 μm.

18. The preparation method according to claim 7, wherein a distance between two opposite side surfaces of each two adjacent barrier layers for blocking water and oxygen is 0.01 to 200 μm.

19. The preparation method according to claim 7, wherein the inorganic film is formed by a process selected from the group consisting of plasma enhanced chemical vapor deposition, atomic layer deposition, and a plasma sputtering method.

20. The preparation method according to claim 7, wherein the material of the inorganic film is selected from the group consisting of SiO₂, SiNₓ, and Al₂O₃.
